(19) United States
(12) Patent Application Publication
(10) Pub. No.: US 2013/0320413 A1
(43) Pub. Date: Dec. 5, 2013

(54) SEMICONDUCTOR STRUCTURE AND METHOD FOR FORMING THE SAME

(71) Applicants: Wei Wang, Beijing (CN); Jing Wang, Beijing (CN); Lei Guo, Beijing (CN)

(72) Inventors: Wei Wang, Beijing (CN); Jing Wang, Beijing (CN); Lei Guo, Beijing (CN)

(21) Appl. No.: 13/576,934

(22) PCT Filed: Jul. 18, 2012
(86) PCT No.: PCT/CN12/78790

§ 371 Date: Aug. 2, 2012

(30) Foreign Application Priority Data
May 30, 2012 (CN) 201210175754.1

(51) Int. Cl. H01L 29/78; H01L 21/336

(52) U.S. Cl. 257/288; 438/197; 257/E29.255; 257/E21.409

(57) ABSTRACT

A semiconductor structure and a method for forming the same are provided. The semiconductor structure comprises: a semiconductor substrate; a trench formed in the semiconductor substrate, in which a rare earth oxide layer is formed in the trench; a channel region partly or entirely formed on the rare earth oxide layer; and a source region and a drain region formed at both sides of the channel region, respectively. A relationship between a lattice constant a of the rare earth oxide layer and a lattice constant b of a semiconductor material of the channel region and/or the source region and the drain region is a=(n±c)b, where n is an integer, c is a mismatch ratio of lattice constants, and 0<c≦15%.

### CROSS-REFERENCE TO RELATED APPLICATION

This application claims priority to and benefits of Chinese Patent Application Serial No. 201210175754.1, filed with the State Intellectual Property Office of P. R. China on May 30, 2012, the entire contents of which are incorporated herein by reference.

### FIELD

The present disclosure relates to semiconductor design and fabrication field, and more particularly to a semiconductor structure and a method for forming the same.

### BACKGROUND

With a development of a semiconductor technology, a feature size of a metal-oxide-semiconductor field-effect transistor (MOSFET) is continuously scaled down. When the feature size reaches a deep submicron or even a nanometer order of magnitude, a series of degeneration effects generally appear, which do not exist or are not obvious when the feature size is a large size, such as a threshold voltage roll-off, a drain region induced barrier lowering (DIBL) or an overlarge leakage current.

In order to solve above problems, one solution is that by producing a corresponding stress in a specific region of a semiconductor device according to a type thereof, a carrier mobility of the device may be enhanced, thus improving a performance of the device. In a deep submicron or nanometer device, the suitable stress is important to improve the performance of the device. Conventional methods for producing the stress comprises: adding a substitutional element in a source region and a drain region to change a lattice constant by epitaxial growth or ion implantation, depositing a stress cap layer after forming a device structure, etc. One of the most primary disadvantages of these conventional methods lies in complicated process and difficulty in adjusting stress type. Moreover, with a further scaling down of the feature size of the device, it is difficult to produce an effective stress by the conventional methods, and thus it is hard to significantly improve the performance of the semiconductor device.

### SUMMARY

The present disclosure is aimed to solve at least one of the problems, particularly problems of overlarge leakage current in a device with small size, difficulty in producing a stress, complicated process and unsatisfactory stress effect.

According to an aspect of the present disclosure, a semiconductor structure is provided. The semiconductor structure comprises: a semiconductor substrate; a trench formed in the semiconductor substrate, in which a rare earth oxide layer is formed in the trench; a channel region partly or entirely formed on the rare earth oxide layer; and a source region and a drain region formed at both sides of the channel region respectively. A relationship between a lattice constant a of the rare earth oxide layer and a lattice constant b of a semiconductor material of the channel region and/or the source region and the drain region is a=(n±c)b, where n is an integer, c is a mismatch ratio of lattice constants, and 0<c≦15%.

In one embodiment, a depth of the trench is not less than 5 nm. To ensure the lattice constant of a surface layer of the rare earth oxide layer not to be affected by the semiconductor substrate and to ensure a larger stress to be induced, the depth of the trench may not be too small.

In one embodiment, a material of the rare earth oxide layer comprises any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1.

In one embodiment, the rare earth oxide layer is formed by epitaxial growth.

In one embodiment, the channel region, the source region and the drain region are formed by crystal growth, which may help to obtain a high quality crystal.

In one embodiment, a thickness of the rare earth oxide layer is equal to or greater than a depth of the trench.

In one embodiment, a thickness of the rare earth oxide layer is less than a depth of the trench.

In one embodiment, when the thickness of the rare earth oxide layer is less than the depth of the trench, a barrier layer is formed at a portion of each side wall of the trench where the rare earth oxide layer is formed.

According to another aspect of the present disclosure, a method for forming a semiconductor structure is provided. The method comprises steps of: S01: providing a semiconductor substrate; S02: forming a trench in the semiconductor substrate; S03: forming a rare earth oxide layer in the trench; S04: forming a channel region on the rare earth oxide layer, and forming a source region and a drain region at both sides of the channel region respectively. A relationship between a lattice constant a of the rare earth oxide layer and a lattice constant b of a semiconductor material of the channel region and/or the source region and the drain region is a=(n±c)b, where n is an integer, c is a mismatch ratio of lattice constants, and 0<c≦15%.

In one embodiment, a depth of the trench is not less than 5 nm. To ensure the lattice constant of a surface layer of the rare earth oxide layer not to be affected by the semiconductor substrate and to ensure a larger stress to be induced, the depth of the trench may not be too small.

In one embodiment, a material of the rare earth oxide layer comprises any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1.

In one embodiment, the rare earth oxide layer is formed by epitaxial growth.

In one embodiment, in Step S03, a thickness of the rare earth oxide layer is equal to or greater than the depth of the trench.

In one embodiment, Step S04 comprises: growing crystals on the rare earth oxide layer to form the channel region, the source region and the drain region respectively, which may help to obtain a high quality crystal.

In one embodiment, in Step S03, a thickness of the rare earth oxide layer is less than the depth of the trench. Therefore, in an alternative embodiment, by controlling a growing condition of the rare earth oxide layer, the rare earth oxide layer may be preferentially vertically grown up from a bottom of the trench so as to prevent holes from being formed in the trench during a growth process. In another alternative embodiment, Step S03 may comprises steps of: S031: forming a barrier layer in the trench; S032: removing a portion of the barrier layer formed on a bottom of the trench and reserving a portion of the barrier layer formed at each sidewall of the trench; S033: growing the rare earth oxide layer in the trench; S034: removing a portion of the barrier layer formed at each sidewall of the trench and uncovered by the rare earth oxide layer.

With the semiconductor structure and the method for forming the same according to an embodiment of the present disclosure, the rare earth oxide layer is formed under the channel region of the semiconductor device. A lattice constant of a rare earth oxide is about twice that of widely used semiconductor materials such as Si, Ge, and group III-V compound semiconductor materials, which means the crystalline rare earth oxides are lattice coincident on these semiconductor materials. The crystalline rare earth oxides can be epitaxially grown on Si, Ge, and some group III-V compound semiconductor materials. By adjusting an element type and content of the rare earth oxide, the lattice constant thereof may be conveniently adjusted to be slightly larger or smaller than twice that of the material of the channel region, the source region or the drain region, thus producing a stress in the channel region, the source region and the drain region of the semiconductor device during an epitaxial growth process because of a lattice constant difference. Advantages of the present disclosure are listed as follows.

(1) Because the lattice constant of the rare earth oxide is varied with a type and a content of a rare earth element in the rare earth oxide, by adjusting the element type and content of the rare earth oxide, a required stress may be induced in the source region and/or the drain region and the channel region.

(2) Because the rare earth oxide layer as a stress source of the semiconductor structure is obtained by crystal growth, compared with a conventional stress cap layer or a stress-engineered trench isolation structure, the stress induced in the channel region by the rare earth oxide in the present disclosure is bigger, and a carrier mobility of the device may be more significantly and effectively enhanced.

(3) By using a crystal characteristic of the rare earth oxide, a conventional complicated method for producing a stress may be replaced by crystal epitaxial growth, thus greatly simplifying a process flow.

Additional aspects and advantages of the embodiments of the present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of the disclosure will become apparent and more readily appreciated from the following descriptions taken in conjunction with the drawings in which:

FIG. 1 is a cross-sectional view of a semiconductor structure according to a first embodiment of the present disclosure;

FIG. 2 is a cross-sectional view of a semiconductor structure according to a second embodiment of the present disclosure;

FIG. 3 is a cross-sectional view of a semiconductor structure according to a third embodiment of the present disclosure;

FIGS. 4-6 are cross-sectional views of intermediate statuses of the semiconductor structure formed in steps of a method for forming the semiconductor structure according to the first embodiment of the present disclosure;

FIG. 7 is a cross-sectional view of an intermediate status of the semiconductor structure formed in steps of a method for forming the semiconductor structure according to the second embodiment of the present disclosure; and

FIGS. 8-11 are cross-sectional views of intermediate statuses of the semiconductor structure formed in steps of a method for forming the semiconductor structure according to the third embodiment of the present disclosure.

### DETAILED DESCRIPTION

Embodiments of the present disclosure will be described in detail in the following descriptions, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure. The embodiments shall not be construed to limit the present disclosure.

It is to be understood that phraseology and terminology used herein with reference to device or element orientation (such as, terms like “longitudinal”, “lateral”, “front”, “rear”, “right”, “left”, “lower”, “upper”, “horizontal”, “vertical”, “above”, “below”, “up”, “top”, “bottom” as well as derivative thereof such as “horizontally”, “downwardly”, “upwardly”, etc.) are only used to simplify description of the present disclosure, and do not alone indicate or imply that the device or element referred to must have or operated in a particular orientation.

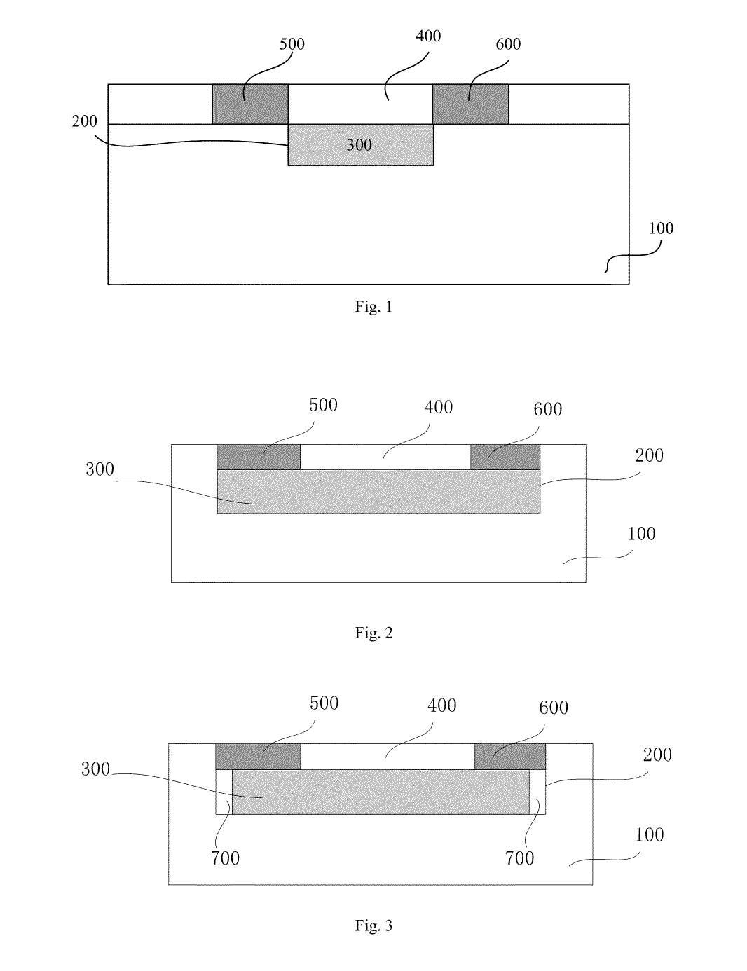

FIG. 1 is a cross-sectional view of a semiconductor structure according to a first embodiment of the present disclosure. As shown in FIG. 1, the semiconductor structure comprises: a semiconductor substrate 100; a trench 200 formed in the semiconductor substrate 100; a rare earth oxide layer 300 formed in the trench 200; a channel region 400 partly or entirely formed on the rare earth oxide layer 300; and a source region 500 and a drain region 600 formed at both sides of the channel region 400 respectively. As shown in FIG. 1, the channel region 400 is entirely formed on the rare earth oxide layer 300. It should be noted that, in an alternative embodiment, the channel region 400 may be partly formed on the rare earth oxide layer 300, that is, a length of the channel region 400 may be larger than that of the trench 200.

In one embodiment, a material of the semiconductor substrate 100 comprises single crystal Si (silicon), single crystal Ge (germanium), SiGe (silicon-germanium) with any Ge content, any group III-V compound semiconductor, SOI (silicon-on-insulator), GeOI (germanium-on-insulator) or other semiconductor substrate materials.

To ensure the lattice constant of a surface layer of the rare earth oxide layer 300 not to be affected by the semiconductor substrate 100 and to ensure a larger stress to be induced, a depth of each of the trench 200 may not be too small. In one embodiment, the depth of the trench 200 may be not less than 5 nm. When a difference between a lattice constant of the rare earth oxide layer 300 and an integral multiple of a lattice constant of a material of the channel region 400 is bigger, that is, a mismatch ratio of lattice constants is bigger, such as 10-15%, a thinner rare earth oxide layer 300 formed in a shallow trench 200 may induce enough stress in the channel region 400. However, when the mismatch ratio of lattice constants is smaller, such as 0.1-1%, a thicker rare earth oxide layer 300 formed in a deep trench 200 is needed to induce enough stress in the channel region 400.

In one embodiment, a material of the rare earth oxide layer 300 may comprise various rare earth oxides and a combination thereof, such as any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1. Specifically, the material of the rare earth oxide layer 300 may comprise Er₂O₃, Gd₂O₃, Nd₂O₃, Pr₂O₃, La₂O₃, etc. Because the lattice constant of the rare earth oxide is varied with a type and a content of a rare earth element in the rare earth oxide, by adjusting the element type and the content of the rare earth oxide, the lattice constant of the rare earth oxide layer 300 under the channel region 400 may be adjusted to be matched with the lattice constant of the material of the channel region 400 and/or the source region 500 and the drain region 600, thus producing a tunable stress in the channel region 400 and/or the source region 500 and the drain region 600. In some embodiments, so called “match” means that a relationship between a lattice constant a of the rare earth oxide layer 300 and a lattice constant b of a semiconductor material of the channel region 400 and/or the source region 500 and the drain region 600 is a=(n±c)b, where n is an integer, c is a mismatch ratio of lattice constants, and 0<c≦15%. For example, in one embodiment, the material of each of the source region 500, the drain region 600 and the channel region 400 may be Si or Ge, and by adjusting the constituent of the rare earth oxide, the lattice constant of the rare earth oxide layer 300 may be adjusted to be slightly larger or smaller than twice that of Si or Ge. If a is just an integral multiple of b, a stress may not be induced in the channel region 400; if a is slightly larger than the integral multiple of b, a tensile stress may be induced in the channel region 400, thus raising an electron mobility in the channel region 400; and if a is slightly smaller than the integral multiple of b, a compressive stress may be induced in the channel region 400, thus raising a hole mobility in the channel region 400. Generally, the mismatch ratio of lattice constants is within 15%.

In a preferred embodiment, the rare earth oxide layer 300 is formed by epitaxial growth, such as an ultra-high vacuum chemical vapor deposition (UHVCVD), an atomic layer deposition (ALD), a metal-organic chemical vapor deposition (MOCVD) or a molecular beam epitaxy (MBE). Because the rare earth oxide layer 300 as a stress source is obtained by crystal growth, compared with a conventional stress cap layer or a stress-engineered trench isolation structure, the stress induced in the channel region by the rare earth oxide in the present disclosure is bigger, and a carrier mobility of the device may be more significantly and effectively enhanced.

In one embodiment, a thickness of the rare earth oxide layer 300 in the trench 200 is substantially equal to (as shown in FIG. 1) or greater than a depth of the trench 200. A material of each of the source region 500, the drain region 600 and the channel region 400 may comprise single crystal Si, single crystal Ge, SiGe with any Ge content, any group III-V compound semiconductor and any group II-VI compound semiconductor. Preferably, the source region 500, the drain region 600 and the channel region 400 may be all formed by crystal growth, which may help to obtain a high quality crystal. It should be noted that thicknesses of the source region 500, the drain region 600 and the channel region 400 may not be overlarge, or else the stress in the channel region 400 induced by the rare earth oxide layer 300 will be released and it will not help to form a source region and a drain region with low resistance so as to cause a poor performance of the device. It should be noted that structures of the channel region, the source region and the drain region and are not limited in the present disclosure, and any structures of the channel region, the source region and the drain region existing in the prior art or to be developed in future art may be applied in the semiconductor structure according to an embodiment of the present disclosure.

In an alternative embodiment, a material of each of the source region 500 and the drain region 600 may also be a metal. By using the metal source region and the metal drain region, a series resistance of the source region and the drain region may be reduced, which may be combined with a stress effect in the channel region to further increase a drive current of the device.

FIG. 2 is a cross-sectional view of a semiconductor structure according to a second embodiment of the present disclosure. The semiconductor structure shown in FIG. 2 is different from the semiconductor structure shown in FIG. 1 in that: the thickness of the rare earth oxide layer 300 in the trench 200 is less than the depth of the trench 200. In this embodiment, the rare earth oxide layer 300 is preferentially vertically grown up from a bottom of the trench 200, so as to prevent holes from being formed in the trench 200 during a growth process. It should be noted that, in this embodiment, the channel region 400 is formed on a portion of the rare earth oxide layer 300, and the source region 500 and the drain region 600 are formed on portions of the rare earth oxide layer 300 at both sides of the channel region 400 respectively, as shown in FIG. 2. In an alternative embodiment, the channel region 400 may be formed on the entire rare earth oxide layer 300, and the source region 500 and the drain region 600 may be located in regions of the semiconductor substrate 100 at both sides of the channel region 400 respectively.

FIG. 3 is a cross-sectional view of a semiconductor structure according to a third embodiment of the present disclosure. The semiconductor structure shown in FIG. 3 is different from the semiconductor structure shown in FIG. 2 in that: a barrier layer 700 is formed at a portion of each side wall of the trench 200 where the rare earth oxide layer 300 is formed, and the source region 500 and the drain region 600 are formed on the rare earth oxide layer 300 and the barrier layer 700 in the trench 200 respectively. Similar to the semiconductor structure shown in FIG. 2, in this embodiment, the channel region 400 is formed on a portion of the rare earth oxide layer 300, and the source region 500 and the drain region 600 are formed on the barrier layers 700 and portions of the rare earth oxide layer 300 at both sides of the channel region 400 respectively, as shown in FIG. 3. In an alternative embodiment, the channel region 400 may be formed on the entire rare earth oxide layer 300, and the source region 500 and the drain region 600 may be located in regions of the semiconductor substrate 100 at both sides of the channel region 400 respectively.

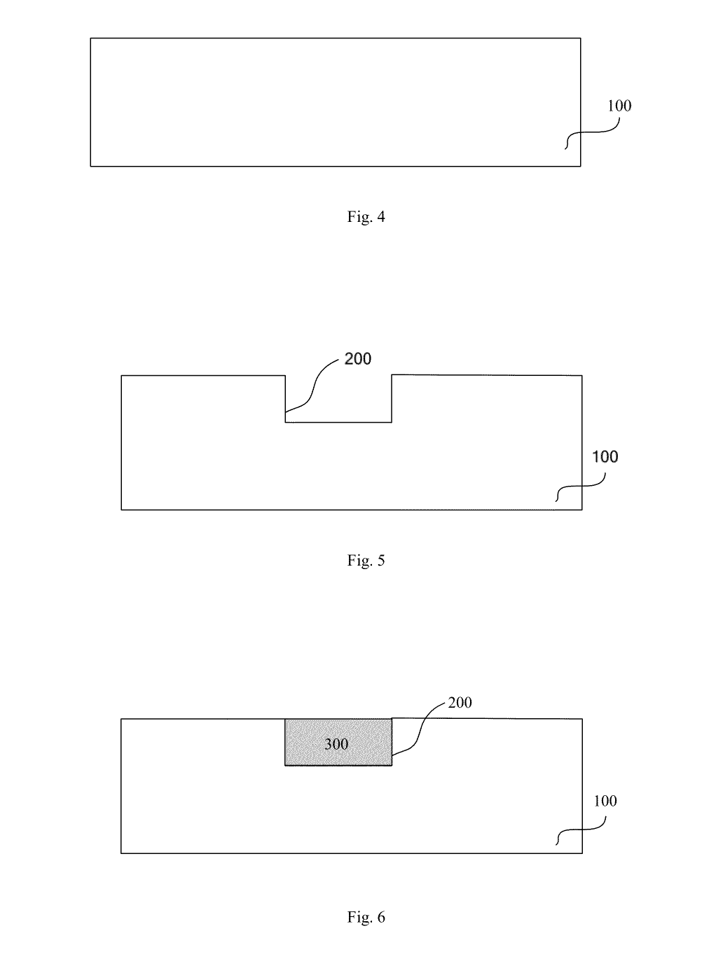

According to another aspect of the present disclosure, a method for forming the abovementioned semiconductor structure is provided. FIGS. 4-6 are cross-sectional views of intermediate statuses of the semiconductor structure formed in steps of a method for forming the semiconductor structure according to the first embodiment of the present disclosure. The method comprises following steps.

Step S101: a semiconductor substrate 100 is provided, as shown in FIG. 4. In one embodiment, a material of the semiconductor substrate 100 may comprise single crystal Si, single crystal Ge, SiGe with any Ge content, any group III-V compound semiconductor, SOI, GeOI or other semiconductor substrate materials.

Step S102: a trench 200 is formed in the semiconductor substrate 100, as shown in FIG. 5. In one embodiment, a region for filling a rare earth oxide layer 300 is defined in the semiconductor substrate 100, and then the trench 200 is formed by etching the semiconductor substrate 100 using a conventional process such as a wet etching process. To ensure the lattice constant of a surface layer of the rare earth oxide layer 300 not to be affected by the semiconductor substrate 100 and to ensure a larger stress to be induced, a depth of the trench 200 may not be too small. In one embodiment, the depth of the trench 200 may be not less than 5 nm.

Step S103: the rare earth oxide layer 300 is formed in the trench 200, as shown in FIG. 6. In this embodiment, a thickness of the rare earth oxide layer 300 in the trench 200 is substantially equal to (as shown in FIG. 6) or greater than a depth of the trench 200. In one embodiment, a material of the rare earth oxide layer 300 may comprise various rare earth oxides and a combination thereof, such as any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1. Specifically, the material of the rare earth oxide layer 300 may comprise Er₂O₃, Gd₂O₃, Nd₂O₃, Pr₂O₃, La₂O₃, etc. In a preferred embodiment, the rare earth oxide layer 300 is formed by epitaxial growth, such as UHVCVD, ALD, MOCVD or MBE. Because the rare earth oxide layer 300 as a stress source is obtained by crystal growth, compared with a conventional stress cap layer or a stress-engineered trench isolation structure, the stress induced in the channel region by the rare earth oxide in the present disclosure is bigger, and a carrier mobility of the device may be more significantly and effectively enhanced. In an alternative embodiment, after the rare earth oxide layer 300 is formed in the trench 200, a device surface may be polished to obtain a flat surface, for example, by a chemical mechanical polishing (CMP).

Step S104: a channel region 400 is formed on the rare earth oxide layer 300, and a source region 500 and a drain region 600 are formed on portions of the semiconductor substrate 100 at both sides of the channel region 400 respectively, as shown in FIG. 1. In one embodiment, a material of each of the source region 500, the drain region 600 and the channel region 400 may comprise single crystal Si, single crystal Ge, SiGe with any Ge content, any group III-V compound semiconductor and any group II-VI compound semiconductor. Preferably, the source region 500, the drain region 600 and the channel region 400 may be all formed by crystal growth, which may help to obtain a high quality crystal. It should be noted that thicknesses of the source region 500, the drain region 600 and the channel region 400 may not be overlarge, or else the stress in the channel region 400 induced by the rare earth oxide layer 300 will be released and it will not help to form a source region and a drain region with low resistance so as to cause a poor performance of the device. In addition, it should be noted that structures and forming processes of the source/drain region and the channel region are not limited in the present disclosure, and any process existing in the art or to be developed in future may be used to form the source/drain region and the channel region.

Because the lattice constant of the rare earth oxide is varied with a type and a content of a rare earth element in the rare earth oxide, by adjusting the element type and content of the rare earth oxide, the lattice constant of the material of the rare earth oxide layer 300 under the channel region 400 may be adjusted to be matched with the lattice constant of the material of the channel region 400 and/or the source region 500 and the drain region 600, that is, the lattice constant of the material of the rare earth oxide layers 400 may be adjusted to be slightly larger or smaller than twice that of the material of the channel region 400 and/or the source region 500 and the drain region 600, thus producing a tunable stress in the channel region 400, the source region 500 and the drain region 600 because of a lattice constant difference.

Alternatively, Step S104 may comprise: forming a metal source region 500 and a metal drain region 600 on portions of the semiconductor substrate 100 at both sides of the channel region 400 respectively. By using the metal source region and the metal drain region, a series resistance of the source region and the drain region may be reduced, which may be matched with a stress effect in the channel region to further increase a drive current of the device.

In one embodiment, a method for forming the semiconductor structure herein above by a MOCVD process will be described below in detail.

Step S101′: a semiconductor substrate is provided. In one embodiment, a material of the semiconductor substrate may be Si with a preferred orientation of <110> or <111>.

Step S102′: a filled region for a rare earth oxide layer is defined in the semiconductor substrate, and then a trench of a rectangular shape is formed in the defined region by etching the semiconductor substrate using a conventional process such as a wet etching process. In this embodiment, a depth of the trench is 30 nm.

Step S103′: a rare earth oxide layer is formed in the trench by MOCVD. For example, for a NMOS device, with Nd(thd)₃ (tris(2,2,6,6-tetramethyl-3,5-heptanedionato)neodymium) as a metal precursor and with O₂ as an oxygen source, the rare earth oxide Nd₂O₃ layer with a thickness of 30 nm is obtained by MOCVD at a temperature of 850° C. Then, the device surface is treated by CMP to get a planarization surface.

Step S104′: a material of a channel region is formed on the rare earth oxide layer by epitaxial growth, and materials of a source region and a drain region are grown on portions of the semiconductor substrate at both sides of the channel region respectively. Because a lattice constant of the rare earth oxide Nd₂O₃ is slightly bigger than twice that of Si, a tensile stress may be induced in the channel region, thus enhancing an electron mobility in the channel region. After the channel region, the source region and the drain region are formed, subsequent processes are performed, for example, a gate stack and a side wall are formed, the source region and the drain region are implanted and activated, and contacts are formed. A transistor having a rare earth oxide layer under the channel region is finally formed.

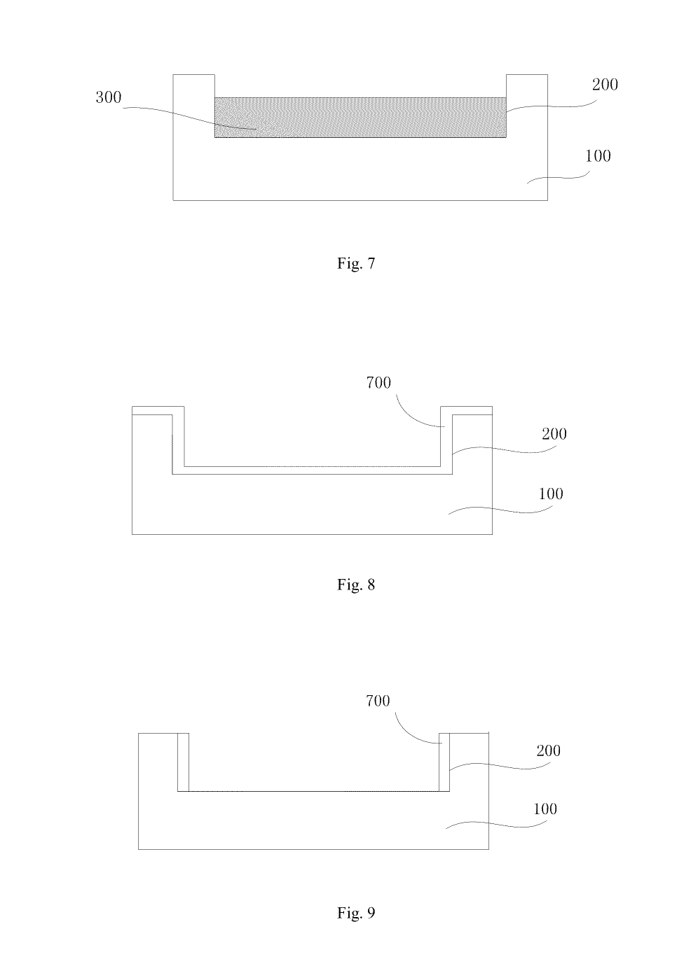

FIG. 7 is a cross-sectional view of an intermediate status of the semiconductor structure formed in steps of a method for forming the semiconductor structure according to the second embodiment of the present disclosure. For conciseness purpose, only steps different from those of the method for forming the semiconductor structure according to the first embodiment of the present disclosure are described below in detail. The method comprises following steps.

Step S201 and Step S202 are substantially the same as Step S101 and Step S102 respectively.

Step S203: a rare earth oxide layer 300 is formed in the trench 200, as shown in FIG. 7. In this embodiment, a thickness of the rare earth oxide layer 300 in the trench 200 is less than a depth of the trench 200. In one embodiment, a material of the rare earth oxide layer 300 may comprise various rare earth oxides and a combination thereof, such as any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1. Specifically, the material of the rare earth oxide layer 300 may comprise Er₂O₃, Gd₂O₃, Nd₂O₃, Pr₂O₃, La₂O₃, etc. In a preferred embodiment, the rare earth oxide layer 300 is formed by epitaxial growth, such as UHVCVD, ALD, MOCVD or MBE. Moreover, by controlling a growing condition of the rare earth oxide layer 300 (for example, a pressure or a temperature), the rare earth oxide layer 300 may be preferentially vertically grown up from a bottom of the trench 200, but hardly laterally grown at sidewalls of the trench 200, thus preventing holes from being formed in the trench 200. Furthermore, by controlling a growing time of the rare earth oxide layer 300, the rare earth oxide layer 300 may be formed in a part of the trench 200. Because the rare earth oxide layer 300 as a stress source of the semiconductor structure is obtained by crystal growth, compared with a conventional stress cap layer or a stress-engineered trench isolation structure, the stress induced in the channel region by the rare earth oxide in the present disclosure is bigger, and a carrier mobility of the device may be more significantly and effectively enhanced.

Step S204: a channel region 400 is formed on the rare earth oxide layer 300, and a source region 500 and a drain region 600 are formed on portions of the rare earth oxide layer 300 at both sides of the channel region 400 respectively, as shown in FIG. 2. In one embodiment, a material of each of the source region 500, the drain region 600 and the channel region 400 may comprise single crystal Si, single crystal Ge, SiGe with any Ge content, any group III-V compound semiconductor and any group II-VI compound semiconductor. Preferably, the source region 500, the drain region 600 and the channel region 400 may be all formed by crystal growth, which may help to obtain a high quality crystal. It should be noted that thicknesses of the source region 500, the drain region 600 and the channel region 400 may not be overlarge, or else the stress in the channel region 400 induced by the rare earth oxide layer 300 will be released and it will not help to form a source region and a drain region with low resistance so as to cause a poor performance of the device. Alternatively, this step may comprise: forming the channel region 400 on the entire rare earth oxide layer 300, and doping portions of the semiconductor substrate 100 at both sides of the channel region 400 to form the source region 500 and the drain region 600 respectively.

In one embodiment, a method for forming the semiconductor structure herein above by a MOCVD process will be described below in detail.

Step S201′: a semiconductor substrate is provided. In one embodiment, a material of the semiconductor substrate may be Si with a preferred orientation of <110> or <111>.

Step S202′: a region for filling a rare earth oxide layer is defined in the semiconductor substrate, and then a trench of a rectangular shape is formed in the defined region by etching the semiconductor substrate using a conventional process such as a wet etching process. In this embodiment, a depth of the trench is 30 nm.

Step S203′: a rare earth oxide layer is formed in the trench by MOCVD. A thickness of the rare earth oxide layer is less than the depth of the trench. For example, with La[N(SiMe₃)₂]₃ as a rare earth oxide source and with O₂ as an oxygen source, the rare earth oxide La₂O₃ layer with a thickness of 15 nm is obtained by MOCVD at a temperature of 800° C.

Step S204′: a channel region is formed on the rare earth oxide layer, and a source region and a drain region are formed on portions of the rare earth oxide layer at both sides of the channel region respectively. In this embodiment, a material of the channel region may be Ge. Because a lattice constant of the rare earth oxide Nd₂O₃ is slightly bigger than twice that of Ge, a tensile stress may be induced in the channel region, thus enhancing an electron mobility in the channel region.

Besides the method of using a preferential vertical epitaxial growth, another method of using a barrier layer to prevent the rare earth oxide layer from being grown at sidewalls of the trench may be adopted to form the semiconductor structure according to the third embodiment of the present disclosure. FIGS. 8-11 are cross-sectional views of intermediate statuses of the semiconductor structure formed in steps of a method for forming the semiconductor structure according to the third embodiment of the present disclosure. For conciseness purpose, only steps different from those of the method for forming the semiconductor structure according to the first embodiment of the present disclosure are described below in detail. The method comprises following steps.

Step S301 and Step S302 are substantially the same as Step S101 and Step S102 respectively.

Step S303 may comprise following steps.

S3031: a barrier layer 700 is formed in the trench 200, as shown in FIG. 8. A material of the barrier layer 700 may be SiN, SiO₂ or other commonly used isolating dielectrics.

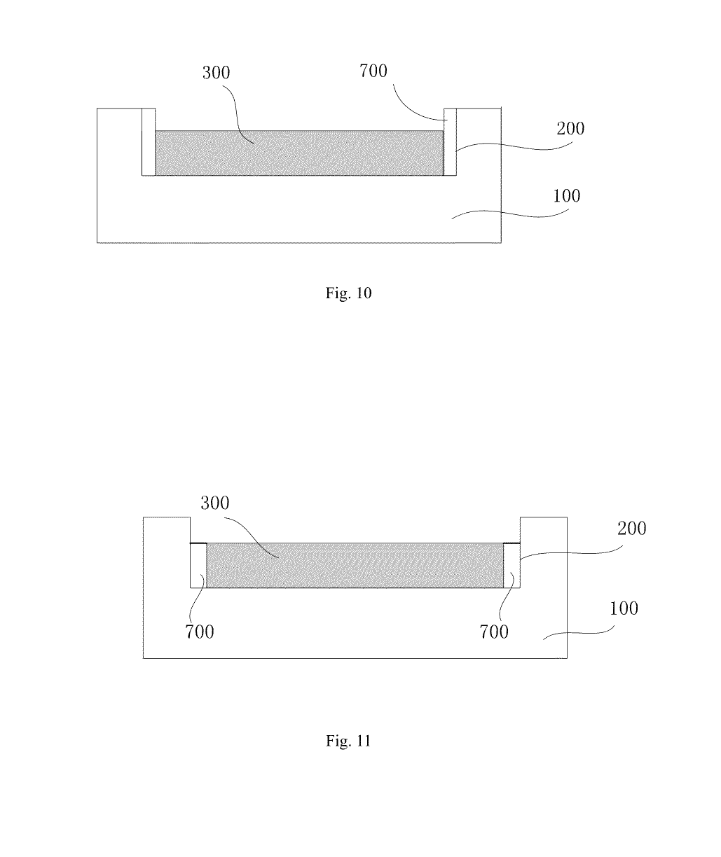

S3032: a portion of the barrier layer 700 formed on the bottom of the trench 200 is removed, and a portion of the barrier layer 700 formed at each sidewall of the trench 200 is reserved, as shown in FIG. 9. Specifically, an anisotropic etching may be performed for the barrier layer 700. By controlling etching process conditions, the bottom of the trench 200 is exposed, while the portion of the barrier layer 700 formed at each sidewall of the trench 200 is reserved.

S3033: the rare earth oxide layer 300 is grown in the trench 200. A thickness of the rare earth oxide layer 300 in the trench 200 is less than a depth of the trench 200, as shown in FIG. 10. Because each sidewall of the trench 200 is protected by the barrier layer 700, the rare earth oxide layer 300 merely grows up from the bottom of the trench 200.

S3034: a portion of the barrier layer 700 formed at each sidewall of the trench 200 and uncovered by the rare earth oxide layer 300 is removed, as shown in FIG. 11. For example, the exposed portion of the barrier layer 700 may be removed by selective etching.

By forming the rare earth oxide layer 300 in the trench 200 in Step S303, because the rare earth oxide layer 300 as a stress source of the semiconductor structure is obtained by crystal growth, compared with a conventional stress cap layer or a stress-engineered trench isolation structure, the stress induced in the channel region by the rare earth oxide in the present disclosure is bigger, and a carrier mobility of the device may be more significantly and effectively enhanced.

Step S304: a channel region 400 is formed on the rare earth oxide layer 300, and a source region 500 and a drain region 600 are formed on the barrier layers 700 and portions of the rare earth oxide layer 300 at both sides of the channel region 400 respectively, as shown in FIG. 3. In one embodiment, a material of each of the source region 500, the drain region 600 and the channel region 400 may comprise single crystal Si, single crystal Ge, SiGe with any Ge content, any group III-V compound semiconductor and any group II-VI compound semiconductor. Preferably, the source region 500, the drain region 600 and the channel region 400 may be all formed by crystal growth, which may help to obtain a high quality crystal. It should be noted that thicknesses of the source region 500, the drain region 600 and the channel region 400 may not be overlarge, or else the stress in the channel region 400 induced by the rare earth oxide layer 300 will be released and it will not help to form a source region and a drain region with low resistance so as to cause a poor performance of the device. Alternatively, this step may comprise: forming the channel region 400 on the entire rare earth oxide layer 300 and the barrier layers 700, and doping portions of the semiconductor substrate 100 at both sides of the channel region 400 to form the source region 500 and the drain region 600 respectively.

With the semiconductor structure and the method for forming the same according to embodiments of the present disclosure, the rare earth oxide layer is formed under the channel region. By adjusting the element type and content of the rare earth oxide layer, the lattice constant of the rare earth oxide layer may be adjusted. Because of lattice constant differences between the rare earth oxide layer and the channel region, between the rare earth oxide layer and the source region and/or between the rare earth oxide layer and the drain region, a tunable stress is induced in the channel region of the semiconductor device during the epitaxial growth process, thus significantly improving the carrier mobility of the semiconductor device. Moreover, by using a crystal characteristic of the rare earth oxide, a conventional complicated method for producing a stress may be replaced by crystal growth, thus greatly simplifying a process flow.

Reference throughout this specification to “an embodiment”, “some embodiments”, “one embodiment”, “an example”, “a specific example”, or “some examples” means that a particular feature, structure, material, or characteristic described in connection with the embodiment or example is included in at least one embodiment or example of the disclosure. Thus, the appearances of the phrases such as “in some embodiments”, “in one embodiment”, “in an embodiment”, “in an example”, “in a specific example”, or “in some examples” in various places throughout this specification are not necessarily referring to the same embodiment or example of the disclosure. Furthermore, the particular features, structures, materials, or characteristics may be combined in any suitable manner in one or more embodiments or examples.

Although explanatory embodiments have been shown and described, it would be appreciated by those skilled in the art that changes, alternatives, and modifications may be made in the embodiments without departing from spirit and principles of the disclosure. Such changes, alternatives, and modifications all fall into the scope of the claims and their equivalents.

1. A semiconductor structure, comprising:
a semiconductor substrate;
a trench formed in the semiconductor substrate, wherein a rare earth oxide layer is formed in the trench;
a channel region partly or entirely formed on the rare earth oxide layer; and
a source region and a drain region formed at both sides of the channel region respectively;
wherein a relationship between a lattice constant a of the rare earth oxide layer and a lattice constant b of a semiconductor material of the channel region and/or the source region and the drain region is a=(n±c)b, where n is an integer, c is a mismatch ratio of lattice constants, and 0<c<15%.

2. The semiconductor structure according to claim 1, wherein a depth of the trench is not less than 5 nm.

3. The semiconductor structure according to claim 1, wherein a material of the rare earth oxide layer comprises any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1.

4. The semiconductor structure according to claim 1, wherein the rare earth oxide layer is formed by epitaxial growth.

5. The semiconductor structure according to claim 1, wherein the source region, the drain region and the channel region are formed by crystal growth.

6. The semiconductor structure according to claim 1, wherein a thickness of the rare earth oxide layer is equal to or greater than a depth of the trench.

7. The semiconductor structure according to claim 1, wherein a thickness of the rare earth oxide layer is less than a depth of the trench.

8. The semiconductor structure according to claim 7, wherein a barrier layer is formed at a portion of each side wall of the trench where the rare earth oxide layer is formed.

9. A method for forming a semiconductor structure, comprising steps of:
S01: providing a semiconductor substrate;
S02: forming a trench in the semiconductor substrate;
S03: forming a rare earth oxide layer in the trench;
S04: forming a channel region on the rare earth oxide layer, and forming a source region and a drain region at both sides of the channel region respectively;
wherein a relationship between a lattice constant a of the rare earth oxide layer and a lattice constant b of a semiconductor material of the channel region and/or the source region and the drain region is a=(n±c)b , where n is an integer, c is a mismatch ratio of lattice constants, and 0<c<15%.

10. The method according to claim 9, wherein a depth of the trench is not less than 5 nm.

11. The method according to claim 9, wherein a material of the rare earth oxide layer comprises any one of (Gd₁₋ₓErₓ)₂O₃, (Gd₁₋ₓNdₓ)₂O₃, (Er₁₋ₓNdₓ)₂O₃, (Er₁₋ₓLaₓ)₂O₃, (Pr₁₋ₓLaₓ)₂O₃, (Pr₁₋ₓNdₓ)₂O₃, (Pr₁₋ₓGdₓ)₂O₃ and a combination thereof, where x is within a range from 0 to 1.

12. The method according to claim 9, wherein the rare earth oxide layer is formed by epitaxial growth.

13. The method according to claim 9, wherein in Step S03, a thickness of the rare earth oxide layer is equal to or greater than the depth of the trench.

14. The method according to claim 13, wherein Step S04 comprises: growing crystals on the rare earth oxide layer to form the channel region, the source region and the drain region respectively.

15. The method according to claim 9, wherein in Step S03, a thickness of the rare earth oxide layer is less than the depth of the trench.

16. The method according to claim 15, wherein Step S03 comprises steps of:
S031: forming a barrier layer in the trench;
S032: removing a portion of the barrier layer formed on a bottom of the trench and reserving a portion of the barrier layer formed at each sidewall of the trench;
S033: growing the rare earth oxide layer in the trench;
S034: removing a portion of the barrier layer formed at each sidewall of the trench and uncovered by the rare earth oxide layer.
